(19) United States
(12) Patent Application Publication
(10) Pub. No.: US 2023/0247799 A1
(43) Pub. Date: Aug. 3, 2023

(54) HEAT PIPE WITH LOCALIZED HEATSINK

(71) Applicant: Cisco Technology, Inc., San Jose, CA (US)

(72) Inventors: Yongguo CHEN, Shanghai (CN); Yaotsan TSAI, San Jose, CA (US); Vic Hong CHIA, Sunnyvale, CA (US); Hua YANG, Tracy, CA (US); Kai CAO, Fremont, CA (US)

(21) Appl. No.: 17/649,589

(22) Filed: Feb. 1, 2022

(51) Int. Cl. H05K 7/20

(52) U.S. Cl. CPC H05K 7/20409; H05K 7/20336

(57) ABSTRACT

An apparatus includes a heat pipe, a first fin, and a second fin. The heat pipe includes a first end and a second end. The heat pipe defines a chamber through which a fluid flows. The first fin is coupled to the heat pipe at the first end. The first fin is arranged to absorb heat from the fluid at the first end such that the fluid at the first end flows back towards the second end. The second fin is coupled to the heat pipe between the first fin and the second end. The second fin is arranged to absorb heat from the fluid as the fluid flows from the second end towards the first end.

### TECHNICAL FIELD

Embodiments presented in this disclosure generally relate to thermal management. More specifically, embodiments disclosed herein relate to a heat pipe with a localized heatsink.

### BACKGROUND

As the power density and power of integrated circuits increases, so does the heat produced by the integrated circuits. Various techniques are used to move the heat away from the integrated circuits, so that the integrated circuits do not overheat. One technique uses heat pipes to carry heat away from the integrated circuits. The performance of the heat pipes, however, suffers in cold ambient conditions (e.g., at or below zero degrees Celsius). Specifically, the heat pipes contain a fluid that evaporates when absorbing heat produced by the integrated circuit. The pressure increase in the fluid causes the fluid to flow towards another end of the heat pipe. The cold ambient condition reduces the pressure of the fluid in the heat pipe, reducing flow. As a result, the heat pipe carries less heat away from the integrated circuit.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 illustrates an example system.

FIG. 2 illustrates an example system.

FIG. 3 illustrates an example system.

FIG. 4 illustrates an example system.

FIG. 5 illustrates an example system.

FIG. 6 is a flowchart of an example method performed in the systems of FIGS. 2-5.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

According to an embodiment, an apparatus includes a heat pipe, a first fin, and a second fin. The heat pipe includes a first end and a second end. The heat pipe defines a chamber through which a fluid flows. The first fin is coupled to the heat pipe at the first end. The first fin is arranged to absorb heat from the fluid at the first end such that the fluid at the first end flows back towards the second end. The second fin is coupled to the heat pipe between the first fin and the second end. The second fin is arranged to absorb heat from the fluid as the fluid flows from the second end towards the first end.

According to another embodiment, a method includes absorbing heat into a fluid at a first end of a heat pipe. The heat pipe defines a chamber through which the fluid flows. The method also includes absorbing, using a first fin coupled to the heat pipe at a second end of the heat pipe, heat from the fluid at the second end such that the fluid at the second end flows back towards the first end and absorbing, using a second fin coupled to the heat pipe between the first fin and the first end, heat from the fluid as the fluid flows from the first end towards the second end.

According to another embodiment, a system includes an integrated circuit, a heat pipe, a first fin, and a second fin. The heat pipe contains a fluid arranged to absorb heat produced by the integrated circuit at a first end of the heat pipe. The heat pipe defines a chamber through which the fluid flows from the first end to a second end of the heat pipe. The first fin is coupled to the second end. The first fin is arranged to absorb heat from the fluid at the second end. The second fin is coupled to the heat pipe between the first end and the first fin. The second fin is arranged to absorb heat from the fluid as the fluid flows from the first end towards the second end.

### Example Embodiments

This disclosure describes a heat pipe with one or more auxiliary heatsinks that are positioned closer to the heat source (e.g., an integrated circuit) than a primary heatsink. For example, the heat pipe may absorb heat from a heat source at one end of the heat pipe and move that heat towards a primary heatsink at the other end of the heat pipe. The heat pipe may include one or more auxiliary heatsinks positioned between the ends of the heat pipe (e.g., an auxiliary heatsink positioned at the same end of the heat pipe as the heat source or an auxiliary heatsink positioned between the heat source and the primary heatsink). The auxiliary heatsinks absorb heat from a fluid flowing in the heat pipe, which effectively shortens the phase change path within the heat pipe. As a result, the auxiliary heatsinks increase the return of the fluid back to the heat source, which increases the amount of heat removed by the heat pipe during cold ambient conditions (e.g., at or below zero degrees Celsius), in particular embodiments.

The auxiliary heatsinks may increase the Q_max of the heat pipe during cold ambient conditions, and hence the cooling performance of the heat pipe during cold ambient conditions. Without the auxiliary heatsinks, a thermal runaway effect may occur in the heat pipe during cold ambient conditions when a power of a heat source, such as an integrated circuit, reaches 700 Watts. During the thermal runaway effect, the heat pipe removes less heat from the heat source than the heat source generates, which causes the temperature of the heat source to increase until the heat source fails. With the auxiliary heatsinks, the heat source power can reach as high as 800 Watts without thermal runaway during cold ambient conditions. In some embodiments, the maximum cooling capability of the heat pipe at −5 degrees Celsius improves from 500 Watts (without the auxiliary heatsinks) to 800 Watts (with the auxiliary heatsinks). Additionally, the thermal resistance of the heat pipe at −5 degrees Celsius and 500 Watts improves from 0.186 Celsius/Watt to 0.1 Celsius/Watt. Adjustments may be made to the profiles of the auxiliary heatsinks so that the heat source can operate at 950 Watts to 1000 Watts without thermal runaway.

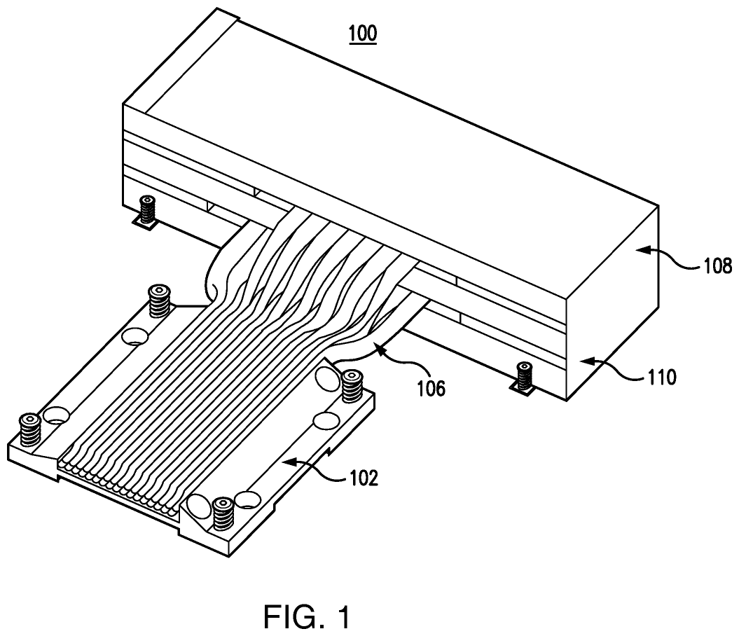

FIG. 1 illustrates an example system 100. As seen in FIG. 1, the system 100 includes a heat transfer block 102, one or more heat pipes 106, and main fins 108 and 110. Generally, the heat pipes 106 carry heat from the heat transfer block 102 to the main fins 108 and 110. The heat is then removed from the system using the fins 108 and 110. For example, air may be circulated on or through the main fins 108 and 110 to carry the heat away from the system 100.

The heat transfer block 102 may be a metal block (e.g., a copper block) that absorbs heat produced by an attached circuit or device. For example, a circuit or device may be attached to the underside of the heat transfer block 102 such that the heat transfer block 102 absorbs heat produced by the circuit or device. The heat pipes 106 may be attached to a topside of the heat transfer block 102 opposite the underside of the heat transfer block 102. The heat pipes 106 absorb the heat from the heat transfer block 102. For example, the heat pipes 106 may contain a fluid that absorbs the heat from the heat transfer block 102. The fluid may vaporize as it absorbs heat from the heat transfer block 102, which increases the fluid pressure within the heat pipes 106. The vapor then flows towards the main fins 108 and 110 at an opposite end of the heat pipes 106. When the fluid reaches the main fins 108 and 110, the main fins 108 and 110 absorb the heat from the fluid. The heat may then be removed from the system 100 using the main fins 108 and 110. When heat is removed from the fluid, the fluid condenses and flows back towards the heat transfer block 102 to absorb more heat from the heat transfer block 102.

During cold ambient conditions, the fluid pressure within the heat pipes 106 may be reduced, causing the flow of the fluid in the heat pipes 106 to also reduce. As a result, less fluid returns to the heat transfer block 102 and less heat is absorbed from the heat transfer block 102. Thus, the efficiency and performance of the heat pipes 106 suffers during cold ambient conditions.

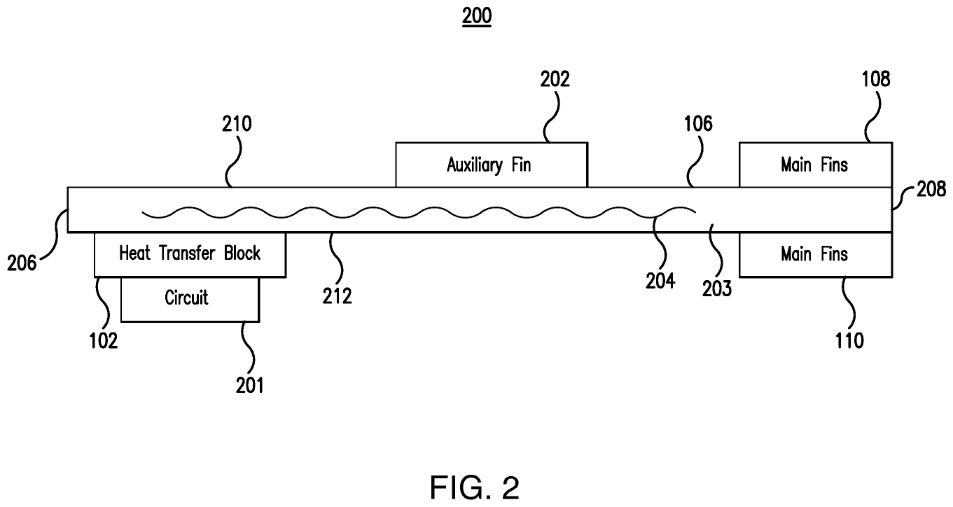

FIG. 2 illustrates an example system 200. As seen in FIG. 2, the system 200 includes the heat transfer block 102, one or more heat pipes 106, the main fins 108 and 110, a circuit 201, and an auxiliary fin 202. Generally, the auxiliary fin 202 absorbs heat from a fluid 204 within the heat pipe 106 as the fluid 204 moves heat from the heat transfer block 102 towards the main fins 108 and 110. As a result, a portion of the fluid 204 condenses before the fluid 204 reaches the main fins 108 and 110. The condensed fluid 204 then flows back towards the heat transfer block 102 to remove additional heat from the heat transfer block 102. In this manner, the phase change path within the heat pipe 106 is shortened, which improves the performance of the heat pipe 106 during cold ambient conditions, in particular embodiments.

The circuit 201 is attached to an underside of the heat transfer block 102. The heat pipe 106 is attached to a top side of the heat transfer block 102 opposite the underside of the heat transfer block 102. The circuit 201 may be any suitable circuit or device. For example, the circuit 201 may be an integrated circuit. During operation, the circuit 201 generates heat that should be removed from the circuit 201 to prevent the circuit 201 from overheating. The heat transfer block 102 is attached to the circuit 201 such that the heat transfer block 102 removes the heat generated by the circuit 201. For example, the heat transfer block 102 may be a metal block that conducts heat generated by the circuit 201 away from the circuit 201. The heat transfer block 102 moves the heat generated by the circuit 201 towards the one or more heat pipes 106.

As discussed previously, the heat pipe 106 absorbs heat from the heat transfer block 102 and carries the heat towards the main fins 108 and 110. Specifically, the heat pipe 106 may define an internal chamber 203 that holds a fluid 204. The chamber may extend along the length of the heat pipe 106 from a first end 206 to a second end 208. The fluid 204 is contained within the chamber 203 such that the fluid 204 may flow within the chamber 203 between the first end 206 and the second end 208. As a result, the fluid 204 may absorb heat from the heat transfer block 102 near the first end 206. The fluid 204 may vaporize as the fluid 204 absorbs heat from the heat transfer block 102. The vapor then flows through the chamber 203 towards the main fins 108 and 110 at the second end 208. When heat is removed from the vapor, the vapor condenses and flows back towards the heat transfer block 102 near the first end 206 to absorb more heat from the heat transfer block 102.

The main fins 108 and 110 are attached to the heat pipe 106 near the second end 208 of the heat pipe 106. The main fin 108 may be attached to a top side 210 of the heat pipe 106, and the main fin 110 may be attached to a bottom side 212 of the heat pipe 106. The top side 210 of the heat pipe 106 may be opposite the bottom side 212 of the heat pipe 106. The main fins 108 and 110 remove heat from the fluid 204 that has flowed to the second end 208 of the heat pipe 106. When the main fins 108 and 110 remove heat from the fluid near the second end 208, that fluid 204 condenses and flows back towards the first end 206 of the heat pipe 106 to absorb additional heat from the heat transfer block 102. The heat absorbed by the main fins 108 and 110 may then be removed from the system 200. For example, air may be circulated on or over the main fins 108 and 110 to carry the heat absorbed by the main fins 108 and 110 away from the system 200.

The auxiliary fin 202 is attached (e.g., by brazing or an adhesive) to the top side 210 of the heat pipe 106 between the first end 206 and the second end 208. As seen in FIG. 2, the auxiliary fin 202 may be attached to the heat pipe 106 between the first end 206 and the main fin 108. The auxiliary fin 202 may be any suitable size or shape. For example, the auxiliary fin 202 may be shorter than, longer than, or the same length as the main fins 108 and 110. The auxiliary fin 202 absorbs heat from the fluid 204 as the fluid 204 flows from the first end 206 towards the main fins 108 and 110. When the auxiliary fin 202 absorbs heat from the fluid 204, some of the fluid 204 condenses and flows back towards the heat transfer block 102 to absorb additional heat from the heat transfer block 102. Some of the fluid 204 may continue flowing past the auxiliary fin 202 towards the main fins 108 and 110. Thus, the auxiliary fin 202 reduces the length of the phase change path for some of the fluid 204 within the heat pipe 106. The auxiliary fin 202 causes some of the fluid 204 to condense, which increases the flow of fluid 204 back towards the heat transfer block 102. As a result, the auxiliary fin 202 improves the performance of the heat pipe 106 during cold ambient conditions, in particular embodiments.

In some embodiments, the auxiliary fin 202 absorbs additional heat from fluid 204 that is flowing back from the main fins 108 and 110 towards the heat transfer block 102. As a result, the fluid 204 may absorb additional heat from the heat transfer block 102 when the fluid 204 reaches the heat transfer block 102. In this manner, the auxiliary fin 202 further improves the performance of the heat pipe 106.

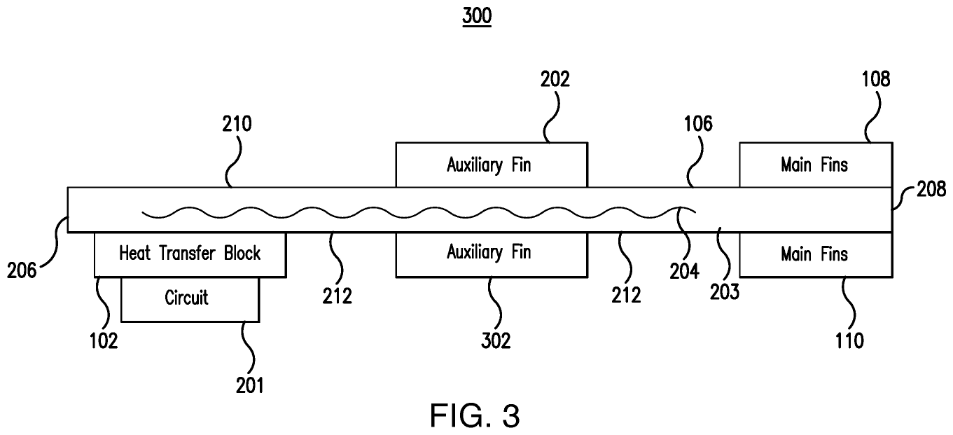

FIG. 3 illustrates an example system 300. As seen in FIG. 3, the system 300 includes a heat transfer block 102, a heat pipe 106, main fins 108 and 110, the circuit 201, the auxiliary fin 202, and an auxiliary fin 302. In particular embodiments, the auxiliary fin 302 removes additional heat from the fluid 204 within the heat pipe 106 before the fluid 204 reaches the main fins 108 and 110. As a result, the auxiliary fin 302 causes additional fluid 204 to condense and flow back towards the heat transfer block 102 to absorb heat from the heat transfer block 102. Thus, the auxiliary fin 302 further improves the performance of the heat pipe 106 during cold ambient conditions, in particular embodiments.

Similar to the system 200 shown in FIG. 2, the circuit 201 is attached to the underside of the heat transfer block 102, and the heat pipe 106 is attached to the top side of the heat transfer block 102. The heat transfer block 102 absorbs heat generated by the circuit 201 and moves that heat towards the heat pipe 106. The fluid 204 within the internal chamber 203 of the heat pipe 106 absorbs the heat from the heat transfer block 102, which vaporizes the fluid 204. The fluid 204 then flows towards the main fins 108 and 110 to carry the heat towards the main fins 108 and 110. The auxiliary fin 202 is attached to a top side 210 of the heat pipe 106 between the first end 206 and the main fin 108. The auxiliary fin 202 removes heat from the fluid 204 as the fluid 204 flows towards the main fins 108 and 110. When the auxiliary fin 202 removes heat from the fluid 204, some of the fluid 204 condenses and flows back towards the heat transfer block 102 to absorb additional heat from the heat transfer block 102.

The auxiliary fin 302 is attached (e.g., by brazing or an adhesive) to a bottom side 212 of the heat pipe 106 opposite the top side 210. The auxiliary fin 302 may be a separate structure from the auxiliary fin 202. In some embodiments, the auxiliary fin 302 is positioned opposing the auxiliary fin 202. The auxiliary fin 302 is positioned between the heat transfer block 102 and the main fin 110. The auxiliary fin 302 may be any suitable size or shape. For example, the auxiliary fin 302 may be shorter than, longer than, or the same length as the main fins 108 and 110. The auxiliary fin 302 absorbs heat from the fluid 204, as the fluid 204 flows towards the main fins 108 and 110. When the auxiliary fin 302 absorbs heat from the fluid 204, a portion of the fluid 204 condenses and flows back towards the heat transfer block 102 to absorb additional heat from the heat transfer block 102. As a result, the auxiliary fin 302 shortens the phase change path within the heat pipe 106 and increases the flow of fluid 204 back towards the heat transfer block 102. Thus, the auxiliary fin 302 improves the performance of the heat pipe 106 during cold ambient conditions, in certain embodiments.

In some embodiments, the auxiliary fin 302 absorbs additional heat from fluid 204 that is flowing back from the main fins 108 and 110 towards the heat transfer block 102. As a result, the fluid 204 may absorb additional heat from the heat transfer block 102 when the fluid 204 reaches the heat transfer block 102. In this manner, the auxiliary fin 302 further improves the performance of the heat pipe 106.

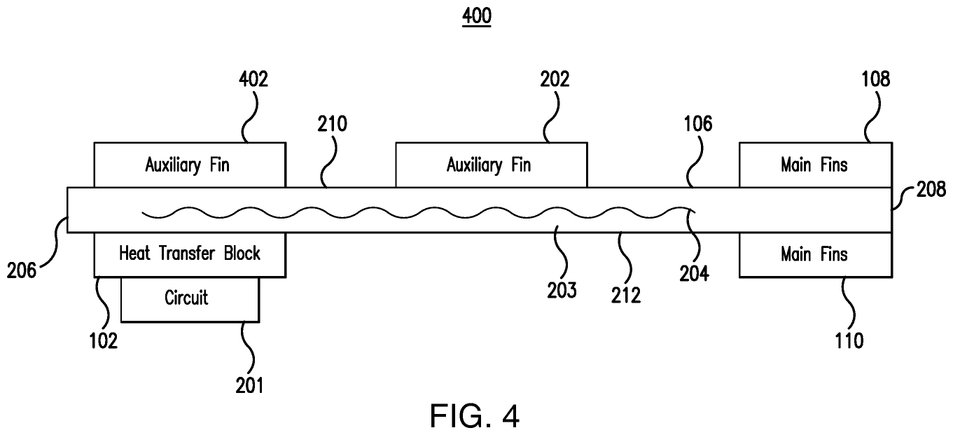

FIG. 4 illustrates an example system 400. As seen in FIG. 4, the system 400 includes a heat transfer block 102, a heat pipe 106, main fins 108 and 110, the circuit 201, the auxiliary fin 202, and an auxiliary fin 402. Generally, the auxiliary fin 402 removes heat from the fluid 204 near the first end 206 of the heat pipe 106 (e.g., before the fluid 204 vaporizes). As a result, the auxiliary fin 402 removes heat from the fluid 204 so that the fluid 204 may absorb additional heat from the heat transfer block 102, which improves the performance of the heat pipe 106, in particular embodiments.

Similar to the system 200 shown in FIG. 2 and the system 300 shown in FIG. 3, the circuit 201 is attached to the underside of the heat transfer block 102, and the heat pipe 106 is attached to the top side of the heat transfer block 102. The heat transfer block 102 absorbs heat generated by the circuit 201 and conducts that heat towards the heat pipe 106. The fluid 204 within the chamber 203 of the heat pipe 106 absorbs the heat from the heat transfer block 102. As the fluid 204 absorbs heat, the fluid 204 vaporizes and flows towards the main fins 108 and 110. The auxiliary fin 202 is attached to the top side 210 of the heat pipe 106 between the first end 206 of the heat pipe 106 and the main fin 108. The auxiliary fin 202 removes heat from the fluid 204 as the fluid 204 flows towards the main fins 108 and 110. When the auxiliary fin 202 removes heat from the fluid 204, a portion of the fluid 204 condenses and flows back towards the heat transfer block 102 to absorb additional heat from the heat transfer block 102. As a result, the auxiliary fin 202 shortens the phase change path within the heat pipe 106 and increases the amount of fluid 204 flowing back to the heat transfer block 102. The auxiliary fin 202 thus improves the performance of the heat pipe 106 during cold ambient conditions, in particular embodiments. The main fins 108 and 110 remove heat from the fluid 204 that reaches the main fins 108 and 110. When the main fins 108 and 110 remove heat from the fluid 204 near the second end 208 of the heat pipe 106, the fluid 204 condenses and flows back towards the heat transfer block 102 to absorb additional heat from the heat transfer block 102.

The auxiliary fin 402 is attached (e.g., by brazing or an adhesive) to the top side 210 of the heat pipe 106 near between the first end 206 of the heat pipe 106 and the auxiliary fin 202. The auxiliary fin 402 may be a separate structure from the auxiliary fin 202. As seen in FIG. 4, the auxiliary fin 402 is positioned near the heat transfer block 102. The auxiliary fin 402 absorbs heat from the fluid 204 near the first end 206 of the heat pipe 106. As a result, the auxiliary fin 402 removes heat from the fluid 204 near the heat transfer block 102. The auxiliary fin 402 thus removes heat from the fluid 204 before the fluid 204 reaches the auxiliary fin 202 and the main fins 108 and 110. Thus, the fluid 204 may absorb additional heat from the heat transfer block 102 before moving towards the auxiliary fin 202 and the main fins 108 and 110.

In some embodiments, the auxiliary fin 402 removes heat from the fluid 204 that is flowing back towards the heat transfer block 102 from the auxiliary fin 202 or the main fins 108 and 110. As a result, the auxiliary fin 402 improves the ability of the fluid 204 that is flowing back to the heat transfer block 102 to absorb additional heat from the heat transfer block 102. In this manner the auxiliary fin 402 improves the performance of the heat pipe 106 during cold ambient conditions, in particular embodiments.

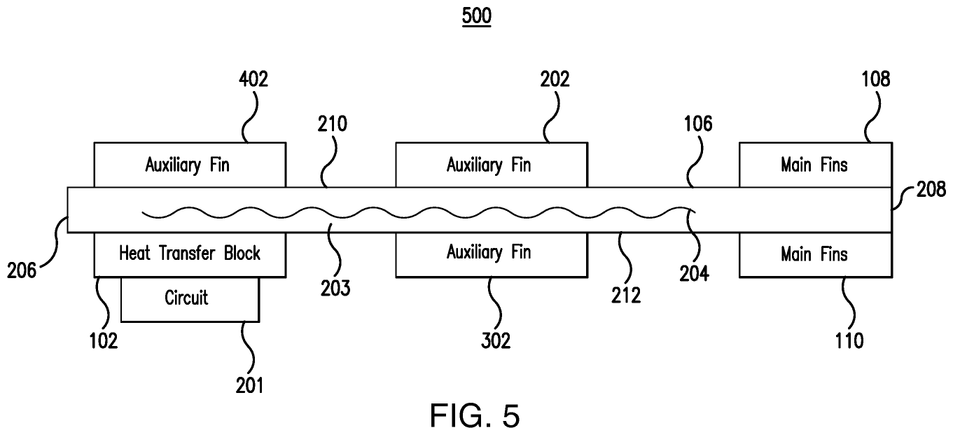

FIG. 5 illustrates an example system 500. As seen in FIG. 5, the system 500 includes a heat transfer block 102, a heat pipe 106, main fins 108 and 110, the circuit 201, the auxiliary fin 202, the auxiliary fin 302, and the auxiliary fin 402. Generally, the auxiliary fins 202, 302 and 402 remove heat from the fluid 204 flowing within the internal chamber 203 of the heat pipe 106. As a result, the flow of the fluid 204 back towards the heat transfer block 102 increases, which improves the performance of the heat pipe 106 during cold ambient conditions, in particular embodiments.

The circuit 201 is attached to the underside of the heat transfer block 102, and the heat pipe 106 is attached to the top side of the heat transfer block 102. The heat transfer block 102 absorbs heat generated by the circuit 201 and moves that heat towards the heat pipe 106. The fluid 204 within the heat pipe 106 absorbs the heat from the heat transfer block 102, which may cause the fluid 204 to vaporize and flow towards the main fins 108 and 110.

The auxiliary fin 202 is attached to the top side 210 of the heat pipe 106 between the first end 206 and the main fin 108. The auxiliary fin 302 is attached to the bottom side 212 of the heat pipe 106 between the heat transfer block 102 and the main fin 110. The auxiliary fin 402 is attached to the top side 210 of the heat pipe 106 between the first end 206 and the auxiliary fin 202. The auxiliary fins 202, 302, and 402 may be separate structures. The auxiliary fin 402 may absorb heat from the fluid 204 near the heat transfer block 102, which allows the fluid 204 to absorb additional heat from the heat transfer block 102. As the fluid 204 flows towards the main fins 108 and 110, the auxiliary fins 202 and 302 remove heat from the fluid 204. When the auxiliary fins 202 and 302 remove heat from the fluid 204, a portion of the fluid 204 condenses and flows back towards the heat transfer block 102 to absorb additional heat from the heat transfer block 102. As a result, the auxiliary fins 202 and 302 shorten the phase change path in the heat pipe 106, which increases the flow of the fluid 204 back towards the heat transfer block 102. Thus, the auxiliary fins 202 and 302 improve the performance of the heat pipe 106 during cold ambient conditions, in particular embodiments. The main fins 108 and 110 remove heat from the fluid 204 that reaches the main fins 108 and 110. When the main fins 108 and 110 remove heat from the fluid 204, the fluid 204 condenses and flows back towards the heat transfer block 102 to absorb additional heat from the heat transfer block 102.

The auxiliary fins 202, 302 and 402 may remove additional heat from the fluid 204 that is flowing back towards the heat transfer block 102. As a result, the auxiliary fins 202, 302 and 402 further improve the fluid's 204 ability to absorb additional heat from the heat transfer block 102. For example, the auxiliary fins 202 and 302 may absorb heat from the fluid 204 that is flowing from the main fins 108 and 110 back towards the heat transfer block 102. As another example, the auxiliary fin 402 may remove additional heat from the fluid 204 that is flowing from the auxiliary fins 202 and 302 or the main fins 108 and 110 back towards the heat transfer block 102. In this manner, the auxiliary fins 202, 302 and 402 further improve the performance of the heat pipe 106, in particular embodiments.

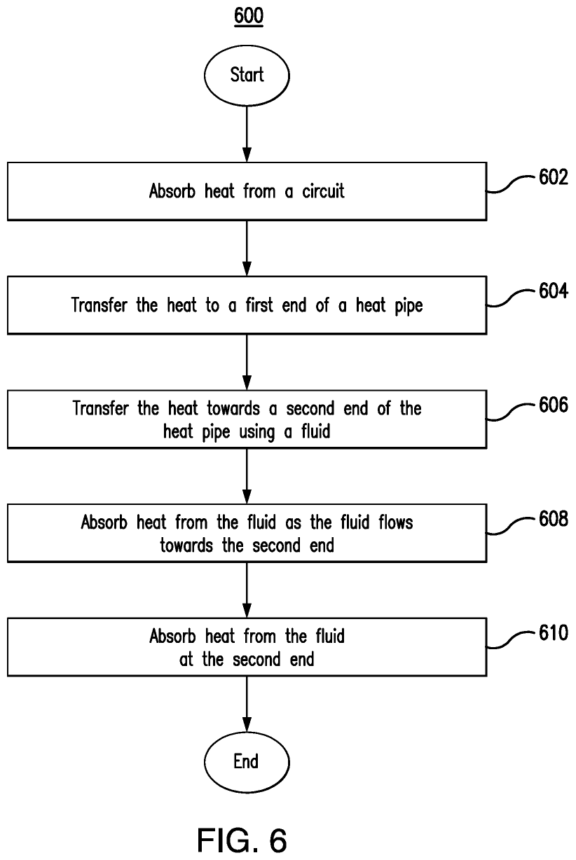

FIG. 6 is a flowchart of an example method 600 performed in the systems 200, 300, 400, and 500 of FIGS. 2 through 5. In particular embodiments, the various components of the systems 200, 300, 400, and 500 perform the steps of the method 600. By performing the method 600, the systems 200, 300, 400, and 500 improve the performance of the heat pipe 106 during cold ambient conditions.

In block 602, the heat transfer block 102 absorbs heat from the circuit 201. The circuit 201 may be an integrated circuit that produces heat during operation. The circuit 201 may be attached to the underside of the heat transfer block 102 such that the heat transfer block 102 absorbs the heat produced by the circuit 201. In block 604, the heat transfer block 102 transfers the heat to the first end 206 of the heat pipe 106. The heat transfer block 102 may be a metal block that conducts the heat generated by the circuit 201 towards the heat pipe 106. The heat pipe 106 may be attached to the top side of the heat transfer block 102. The heat pipe 106 may define an internal chamber 203 that contains a fluid 204 that absorbs the heat from the heat transfer block 102.

In block 606, the fluid 204 transfers the heat towards the second end 208 of the heat pipe 106. As the fluid 204 absorbs heat from the heat transfer block 102 near the first end 206 of the heat pipe 106, the fluid 204 may vaporize and increase the fluid pressure within the heat pipe 106. The vapor then flows towards the second end 208 of the heat pipe 106.

In block 608, the auxiliary fin 202 absorbs heat from the fluid 204 as the fluid 204 flows towards the second end 208. The auxiliary fin 202 may be attached to a top side 210 of the heat pipe 106 between the first end 206 of the heat pipe 106 and the main fin 108. The main fin 108 may be attached to the heat pipe 106 near the second end 208 of the heat pipe 106. When the auxiliary fin 202 absorbs heat from the fluid 204, some of the fluid 204 condenses and flows back towards the first end 206 of the heat pipe 106 to absorb additional heat from the heat transfer block 102. As a result, the auxiliary fin 202 shortens the phase change path within the heat pipe 106, which improves the performance of the heat pipe 106 during cold ambient conditions, in certain embodiments.

In block 610, the main fins 108 and 110 absorb heat from the fluid 204 at the second end 208 of the heat pipe 106. When the main fins 108 and 110 absorb heat from the fluid 204, the fluid 204 condenses and flows back towards the first end 206 of the heat pipe 106 to absorb additional heat from the heat transfer block 102. In certain embodiments, the auxiliary fin 202 absorbs additional heat from the fluid 204 as the fluid 204 flows back towards the heat transfer block 102, which increases the amount of additional heat that the fluid 204 may absorb from the heat transfer block 102 when the fluid 204 reaches the heat transfer block 102. Heat absorbed by the main fins 108 and 110 may be removed from the system 200, 300, 400, or 500. For example, air may be circulated on or over the main fins 108 and 110 to carry the heat absorbed by the main fins 108 and 110 away from the systems 200, 300, 400, or 500.

In summary, a heat pipe 106 has one or more auxiliary heatsinks that are positioned closer to the heat source (e.g., an integrated circuit) than a primary heatsink. For example, the heat pipe 106 may absorb heat from a heat source at one end 206 of the heat pipe 106 and move that heat towards a primary heatsink (e.g., main fins 108 and 110) at the other end 208 of the heat pipe 106. The heat pipe 106 may include one or more auxiliary heatsinks positioned between the ends 206 and 208 of the heat pipe 106 (e.g., an auxiliary fin 402 positioned at the same end of the heat pipe as the heat source or auxiliary fins 202 and 302 positioned between the heat source and the primary heatsink). The auxiliary heatsinks absorb heat from a fluid 204 flowing in the heat pipe 106, which effectively shortens the phase change path within the heat pipe 106. As a result, the auxiliary heatsinks increase the return of the fluid 204 back to the heat source, which increases the amount of heat removed by the heat pipe 106 during cold ambient conditions, in particular embodiments.

### Check Disclosure for Details

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

As will be appreciated by one skilled in the art, the embodiments disclosed herein may be embodied as a system, method or computer program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, embodiments may take the form of a computer program product embodied in one or more computer readable medium(s) having computer readable program code embodied thereon.

Program code embodied on a computer readable medium may be transmitted using any appropriate medium, including but not limited to wireless, wireline, optical fiber cable, RF, etc., or any suitable combination of the foregoing.

Computer program code for carrying out operations for embodiments of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described herein with reference to flowchart illustrations and/or block diagrams of methods, apparatuses (systems), and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the block(s) of the flowchart illustrations and/or block diagrams.

These computer program instructions may also be stored in a computer readable medium that can direct a computer, other programmable data processing apparatus, or other device to function in a particular manner, such that the instructions stored in the computer readable medium produce an article of manufacture including instructions which implement the function/act specified in the block(s) of the flowchart illustrations and/or block diagrams.

The computer program instructions may also be loaded onto a computer, other programmable data processing apparatus, or other device to cause a series of operational steps to be performed on the computer, other programmable apparatus or other device to produce a computer implemented process such that the instructions which execute on the computer, other programmable data processing apparatus, or other device provide processes for implementing the functions/acts specified in the block(s) of the flowchart illustrations and/or block diagrams.

The flowchart illustrations and block diagrams in the Figures illustrate the architecture, functionality, and operation of possible implementations of systems, methods, and computer program products according to various embodiments. In this regard, each block in the flowchart illustrations or block diagrams may represent a module, segment, or portion of code, which comprises one or more executable instructions for implementing the specified logical function(s). It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

In view of the foregoing, the scope of the present disclosure is determined by the claims that follow.

We claim:

1. An apparatus comprising:
a heat pipe comprising a first end and a second end, wherein the heat pipe defines a chamber through which a fluid flows;
a first fin coupled to the heat pipe at the first end, wherein the first fin is arranged to absorb heat from the fluid at the first end such that the fluid at the first end flows back towards the second end; and
a second fin coupled to the heat pipe between the first fin and the second end, wherein the second fin is arranged to absorb heat from the fluid as the fluid flows from the second end towards the first end.

2. The apparatus of claim 1, further comprising a third fin coupled to a bottom side of the heat pipe at the first end, wherein the first fin is coupled to a top side of the heat pipe opposite the bottom side, and wherein the third fin is arranged to absorb heat from the fluid at the first end.

3. The apparatus of claim 1, further comprising a third fin coupled to a bottom side of the heat pipe between the first end and the second end, wherein the second fin is coupled to a top side of the heat pipe opposite the bottom side, and wherein the third fin is arranged to absorb heat from the fluid as the fluid flows from the second end towards the first end.

4. The apparatus of claim 1, further comprising a third fin coupled to the heat pipe at the second end such that the second fin is positioned between the first fin and the third fin.

5. The apparatus of claim 1, wherein the second fin is shorter than the first fin.

6. The apparatus of claim 1, further comprising a metal block coupled to the heat pipe at the second end.

7. The apparatus of claim 6, further comprising an integrated circuit coupled to the metal block, wherein the fluid is arranged to absorb heat produced by the integrated circuit.

8. The apparatus of claim 1, wherein a portion of the fluid condenses when the second fin absorbs heat from the fluid as the fluid flows from the second end towards the first end, wherein the portion of the fluid flows towards the second end after condensing.

9. The apparatus of claim 1, wherein a portion of the fluid condenses when the first fin absorbs heat from the fluid at the first end, wherein the portion of the fluid flows towards the second end after condensing.

10. A method comprising:
absorbing heat into a fluid at a first end of a heat pipe, wherein the heat pipe defines a chamber through which the fluid flows;
absorbing, using a first fin coupled to the heat pipe at a second end of the heat pipe, heat from the fluid at the second end such that the fluid at the second end flows back towards the first end; and
absorbing, using a second fin coupled to the heat pipe between the first fin and the first end, heat from the fluid as the fluid flows from the first end towards the second end.

11. The method of claim 10, further comprising absorbing, using a third fin coupled to a bottom side of the heat pipe at the second end, wherein the first fin is coupled to a top side of the heat pipe opposite the bottom side.

12. The method of claim 10, further comprising absorbing, using a third fin coupled to a bottom side of the heat pipe between the first end and the second end, heat from the fluid as the fluid flows from the first end towards the second end, wherein the second fin is coupled to a top side of the heat pipe opposite the bottom side.

13. The method of claim 10, further comprising absorbing, using a third fin coupled to the heat pipe at the first end such that the second fin is positioned between the first fin and the third fin, heat from the fluid at the first end.

14. The method of claim 10, wherein the second fin is shorter than the first fin.

15. The method of claim 10, wherein the heat absorbed into the fluid at the first end is from a metal block coupled to the heat pipe at the first end.

16. The method of claim 15, wherein the heat absorbed into the fluid at the first end is produced by an integrated circuit coupled to the metal block.

17. The method of claim 10, wherein a portion of the fluid condenses when the second fin absorbs heat from the fluid as the fluid flows from the first end towards the second end, wherein the portion of the fluid flows towards the first end after condensing.

18. The method of claim 10, wherein a portion of the fluid condenses when the first fin absorbs heat from the fluid at the second end, wherein the portion of the fluid flows towards the first end after condensing.

19. A system comprising:
an integrated circuit;
a heat pipe containing a fluid arranged to absorb heat produced by the integrated circuit at a first end of the heat pipe, the heat pipe defining a chamber through which the fluid flows from the first end to a second end of the heat pipe;
a first fin coupled to the second end, the first fin arranged to absorb heat from the fluid at the second end; and
a second fin coupled to the heat pipe between the first end and the first fin, the second fin arranged to absorb heat from the fluid as the fluid flows from the first end towards the second end.

20. The system of claim 19, further comprising a third fin coupled to a bottom side of the heat pipe between the first end and the second end, wherein the second fin is coupled to a top side of the heat pipe opposite the bottom side, and wherein the third fin is arranged to absorb heat from the fluid as the fluid flows from the first end towards the second end.
